(19) United States
(12) Patent Application Publication
(10) Pub. No.: US 2009/0304918 A1
(43) Pub. Date: Dec. 10, 2009

(54) Method and apparatus for coating objects

(76) Inventor: Georg Mayer, Capetown (ZA)

Correspondence Address: JOEL D. SKINNER, JR.;SKINNER AND ASSOCIATES, 212 COMMERCIAL ST., HUDSON, WI, 54016, US

(21) Appl. No.: 11/919,171

(22) PCT Filed: Apr. 25, 2006
(86) PCT No.: PCT/IB2006/000996

§ 371 Date: Sep. 19, 2008

(30) Foreign Application Priority Data
Apr. 25, 2005 (ZA) 2005/03324

(51) Int. Cl. B05D 5/06; C23C 16/54

(52) U.S. Cl. 427/164; 118/722

(57) ABSTRACT

A coating apparatus (10) includes a chamber (12) defining a cavity (16), a diffuser (20), a vacuum valve (26), a burst valve (28), and a vacuum pump (30). In use, the chamber (12) is heated before a batch of lenses (46) to be coated are placed within the cavity (16) together with a tablet (42) impregnated with a coating substance. Air is then pumped from the cavity (16) until the pressure has been lowered to between 1×10-3 to 1×10-1 mbar (absolute pressure). The source tablet (42) is then heated by heater (38) to release a coating substance in vapour form. The burst valve (28) is then opened intermittently to allow small bursts of air to flow into the cavity (16). The diffuser (20) imparts swirling movement to the air burst as it enters the cavity (16), so that the air swirls around within the cavity thereby causing the vapour of the coating substance to be evenly distributed within the cavity and condense evenly on the lenses (46).

### FIELD OF INVENTION

THIS INVENTION relates to coating surfaces of objects. In particular, the invention relates to a method and apparatus for coating optical lenses.

### BACKGROUND TO THE INVENTION

Optical lenses are often coated with, for example, a non-reflective or hardening substance. This is typically done by allowing microscopic droplets of a coating substance to condense on the lenses in a partial vacuum. The condensate adheres to the lenses forming a thin film on the lenses.

The droplets of the coating substances are so small that their travel from a source to the lens could be disrupted by the presence of air molecules or other gases and consequently, this process is usually conducted in rough vacuum, i.e. 1×10⁻³ to 1×10⁻¹ mbar (absolute pressure), or high vacuum, i.e. 1×10⁻⁶ to 1×10⁻³ mbar (absolute pressure). The high or rough vacuum also assists in rapid evaporation of the coating substances, which are usually supplied in tablet form, wherein the tablet is impregnated with the coating substance.

As a result of the vacuum, droplets emitted from the source tablets travel directly to the lenses with negligible disruption to their path of travel. In order to ensure coating of both sides of the lenses by a coating substance evaporated from a single source, either the source has to move relative to the lenses or the lenses relative to the source. The coating process is thus cumbersome and complicated needing relative movement between the lenses and the source.

### SUMMARY OF INVENTION

According to a first aspect of the invention there is provided a coating apparatus comprising:

a chamber defining a cavity;
support means for supporting an object in the cavity;
vacuum means for creating at least a partial vacuum in the chamber;
vapour means for releasing a coating substance in vapour form in the cavity, to be deposited on the object; and
air burst means for causing turbulent movement of air within the chamber, to evenly distribute the coating substance in vapour form in the cavity

The air burst means may include a valve that is open to the chamber at one side and open to a source of pressure higher than the pressure in the chamber at the other side and which may be operable to be opened and closed thereby to cause a burst of air to enter the chamber.

The air burst means may include a diffuser past which air flowing into the chamber flows.

The diffuser may be designed and configured to impart swirling movement to the air as it is introduced into the cavity.

The vacuum means may be configured to lower pressure in the cavity to an absolute pressure of between 1×10⁻³ and 1×10⁻¹ mbar.

The vapour means may include a source heater and a source tablet containing the coating substance which is heated by the source heater, in use.

The coating apparatus may include a heating element for heating a wall of the chamber.

According to a second aspect of the invention, there is provided a method of coating a surface of an object, which method includes:

placing the object in a cavity defined within a chamber, with the surface exposed to the cavity;
lowering the pressure in the cavity to a pressure below atmospheric pressure;
releasing a coating substance into the cavity, in vapour form, to be deposited on the surface of the object; and
allowing one or more bursts of air to enter the chamber thereby to cause turbulent movement of air within the chamber, to evenly distribute the coating substance in vapour form in the cavity.

The method may include imparting swirling movement to the air when the or each burst of air enters the chamber.

Releasing the coating substance into the cavity in vapour form may be achieved by heating a source tablet containing the coating substance, thereby to cause evaporation of the coating substance.

The pressure in the cavity may be lowered to an absolute pressure of between 1×10⁻³ and 1×10⁻¹ mbar.

The pressure within the cavity may be raised to an absolute pressure of between 1×10⁻¹ and 1×10² mbar by the bursts of air.

The or each burst of air may enter the cavity via a diffuser which may be configured to induce the turbulent movement of air within the cavity.

The method may include heating the chamber before the objects are placed within the chamber so that the chamber may be at a relatively higher temperature than the objects within the chamber, when the coating substance is caused to evaporate to form a vapour.

The method may include maintaining the raised pressure in the cavity for an extended period before the pressure in the chamber is returned to atmospheric pressure and the objects are removed.

The method may include coating surfaces of objects in the form of optical lenses, which are supported within the cavity in a stacked arrangement.

### BRIEF DESCRIPTION OF THE DRAWINGS

Further features of the invention are described hereinafter by way of a non-limiting example of the invention, with reference to and as illustrated in the accompanying diagrammatic drawing. In the drawings:

FIG. 1 shows a diagrammatic side view of the layout of an apparatus in accordance with the invention;

FIG. 2 shows a diagrammatic front view of the layout of an apparatus of FIG. 1;

FIG. 3 shows a schematic fragmentary three-dimensional front view of the apparatus of FIG. 1, with support racks omitted;

FIG. 4 shows a schematic front view of a diffuser of the apparatus of FIG. 1;

FIG. 5 shows a schematic front view of a source heating element of the apparatus of FIG. 1; and

FIG. 6 shows a schematic fragmentary three-dimensional front view of the apparatus of FIG. 1, showing supporting racks and lenses supported on the supporting racks.

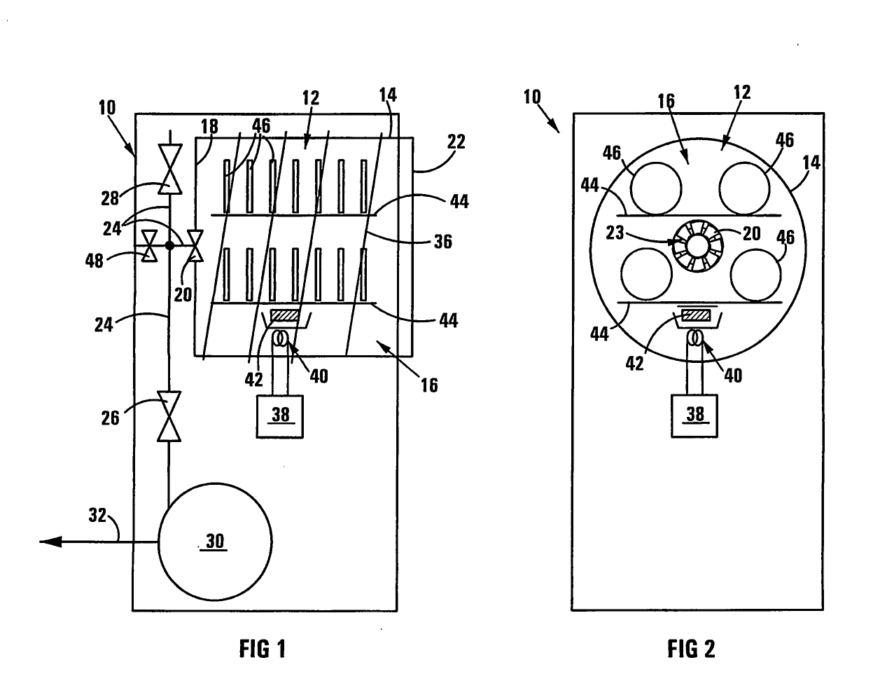

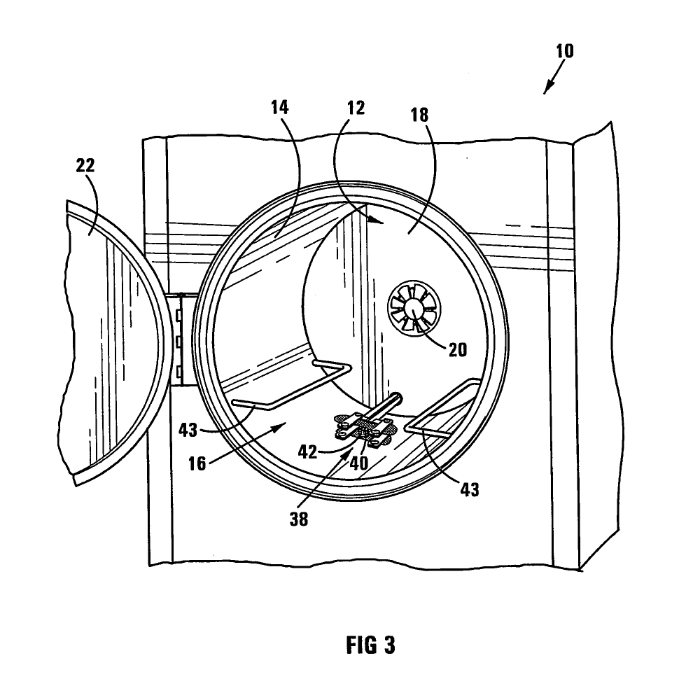

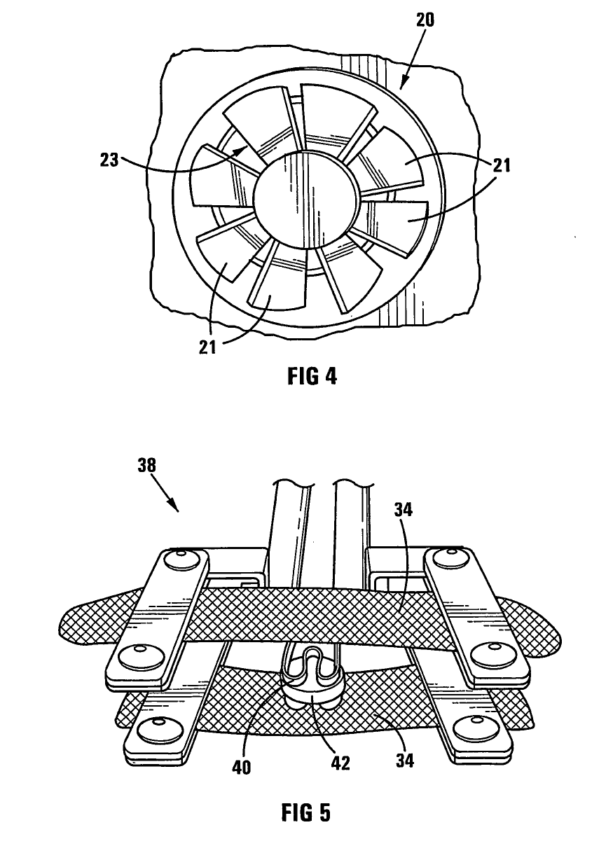

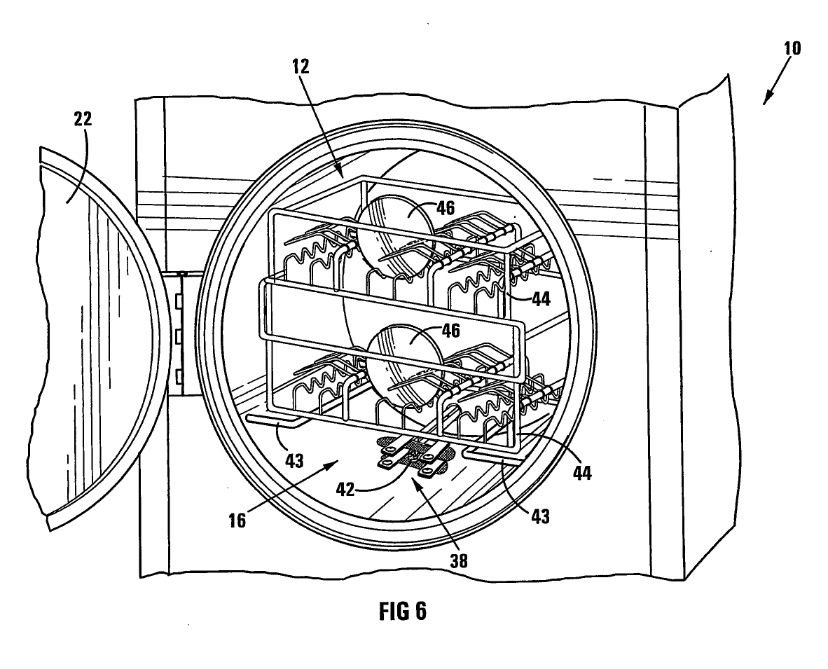

### DESCRIPTION OF THE PREFERRED EMBODIMENT

Referring to the drawings, a coating apparatus in accordance with the invention is generally indicated by reference 10. The apparatus 10 includes a chamber 12, a diffuser 20, a vacuum valve 26, air burst means in the form of burst valve 28, vacuum means in the form of a vacuum pump 30, and a vent valve 48.

The chamber 12 defines an inner cavity 16. The chamber 12 comprises a cylindrical side wall 14, a rear wall 18 and an access opening that is closed by a disc shaped door 22. The diffuser 20 is fixed centrally in an opening 23 in the rear wall 18.

The diffuser 20 includes curved vanes 21. The opening 23 in the rear wall is connected via tubes 24 to the vacuum valve 26, the burst valve 28 and the vent valve 48.

The burst valve 28 connects to the tubes 24 at one side and to the atmosphere at the other side. When the burst valve is open air can flow freely from the atmosphere to the cavity 16.

The vacuum valve 26 is connected to the tubes 24 at one side and to the vacuum pump 30 at the other side. When the vacuum valve 26 is open and the vacuum pump 30 is on, the vacuum pump is operable to draw a partial vacuum in the chamber 12.

The vacuum pump 30 includes an exhaust 32 extending to atmosphere.

The vent valve 48 is connected to the opening 23 via the tubes 24 at one side and to the atmosphere at the other side.

The chamber 12 is provided with a chamber heater that includes a helical heating element 36 wound around the side walls 14 of the chamber 12. It is to be appreciated that the rear wall 18 and door 22 can similarly be heated.

The apparatus 10 includes vapour means in the form of a source heater 38 and a source tablet 42 that is impregnated with a coating substance. The source heater 38 includes a heating element 40 and electrically heated stainless steel meshes 34 disposed above and below the heating element 40. Inside the cavity 16, the source tablet 42, is held in the heating element 40.

The apparatus 10 includes support means in the form of support rails 43 and support racks 44 which are supported on the support rails 43 in the cavity 16. A number of lenses 46 are supported on the racks 44 in a side-by-side arrangement, or any other arrangement in which the surfaces of the lenses are exposed to the cavity 16.

In use, the chamber 12 is heated by the helical heating element 36 of the chamber heater up to a temperature of about 85° C. while the cavity is at ambient pressure. A batch of lenses 46 to be coated, is initially outside the chamber 12. After the chamber has been heated to 85° C., the lenses are placed on the racks 44 which are located within the cavity 16. A tablet 42 is inserted into the source heater 38 where it is held in the heating element 40. The chamber door 22 is closed and the vacuum valve 26 is opened while the burst valve 28 is closed. The pump 30 is actuated so that air is pumped from the cavity 16 through the opening 23, the tubes 24 and the vacuum valve 26 until the pressure within the cavity has been lowered to a pressure between 1×10⁻³ to 1×10⁻¹ mbar (absolute pressure). This type of vacuum is referred to as “rough vacuum”.

Once the pressure within the cavity 16 has been lowered to rough vacuum, the vacuum valve 26 is closed with the pump 30 still running. The source tablet 42 is then heated to a temperature of about 500° C. by the source heater 38. The tablet 42 acts as a source for the coating substance that is released in vapour form from the tablet. After approximately 60 to 90 seconds of heating by the source heater 38, the coating substance evaporates from the tablet 42 to form a vapour. The rate of release of the coating substance is enhanced by the rough vacuum.

Once a sufficient quantity of the coating substance has been released into the cavity 16, the burst valve 28 is opened intermittently for short periods of time to allow small bursts of air to flow from the atmosphere, through the opening 23, into the cavity 16. The angled vanes 21 of the diffuser 20 impart helical turbulence or swirling movement to the air burst as it enters the cavity 16, so that the air swirls around within the cavity. The initial air bursts raise the pressure in the chamber from rough vacuum to a pressure between 1×10⁻¹ and 1×10² mbar (absolute pressure) known as “air avoidance vacuum”. Turbulence from the air bursts is not attainable in rough vacuum but is induced when the chamber is in air avoidance vacuum. Once the chamber 12 is in air avoidance the pressure within the cavity is not increased significantly by the air bursts because of the lower differential in pressure between the atmosphere and the cavity 16 in air avoidance vacuum as opposed to rough vacuum.

The swirling air movement within the cavity 16 that results from turbulence induced by the air bursts, causes the vapour of the coating substance to be evenly distributed within the cavity, so that the coating substance is deposited evenly on and adheres to both of the lens surfaces of each of the lenses in the batch via condensation of the vapour on the lenses.

While the coating substance condenses on the lenses 46, the lenses are at a lower temperature relative to the rest of the chamber, because they were at ambient temperature when introduced into the already heated chamber. This provides for increased condensation of the coating substance on the lenses 46 as opposed to the inside of the chamber 12.

In the pressure range of the air avoidance vacuum, the presence of air molecules is not sufficient to disrupt travel of the coating substance vapours from the tablet source 42 to the lenses 46 detrimentally, but the movement of the air within the cavity 16 causes even distribution of the coating substance vapours within the cavity.

After the last burst of air has entered the cavity 16, the burst valve 28 remains closed and the air avoidance vacuum is maintained within the cavity 16 to allow for condensation of the coating substance on the lenses 46 to continue during a soaking period. After the soaking period, the vacuum valve 26 is opened briefly so that air in the chamber 12 is pumped from the chamber to remove all traces of chemicals and gasses. The vent valve 48 is then opened and air enters the cavity 16 via the opening 32 until the cavity is at ambient pressure and the door 22 can be opened and the racks 44 and lenses 46 removed from the cavity.

1. A coating apparatus comprising:
a chamber defining a cavity;
support means for supporting an object in the cavity;
vacuum means for creating at least a partial vacuum in the chamber;
vapour means for releasing a coating substance in vapour form in the cavity, to be deposited on the object; and air burst means for causing turbulent movement of air within the chamber, to evenly distribute the coating substance in vapour form in the cavity.

2. A coating apparatus as claimed in claim 1, wherein the air burst means includes a valve that is open to the chamber at one side and open to a source of pressure higher than the pressure in the chamber at the other side and which is operable to be opened and closed thereby to cause a burst of air to enter the chamber.

3. A coating apparatus as claimed in claim 1, wherein the air burst means includes a diffuser past which air flowing into the chamber flows.

4. A coating apparatus as claimed in claim 3, wherein the diffuser is designed and configured to impart swirling movement to the air as it is introduced into the cavity.

5. A coating apparatus as claimed in claim 1, wherein the vacuum means is configured to lower pressure in the cavity to an absolute pressure of between 1×10″³ and 1×10″¹ mbar.

6. A coating apparatus as claimed in claim 1, wherein the vapour means includes a source heater and a source tablet containing the coating substance which is heated by the source heater, in use.

7. A coating apparatus as claimed in claim 1, wherein the coating apparatus includes a heating element for heating a wall of the chamber.

8. A method of coating a surface of an object, which method includes:
placing the object in a cavity defined within a chamber, with the surface exposed to the cavity;
lowering the pressure in the cavity to a pressure below atmospheric pressure;
releasing a coating substance into the cavity, in vapour form, to be deposited on the surface of the object; and allowing one or more bursts of air to enter the chamber thereby to cause turbulent movement of air within the chamber, to evenly distribute the coating substance in vapour form in the cavity.

9. A method as claimed in claim 8, which includes imparting swirling movement to the air when the or each burst of air enters the chamber.

10. A method as claimed in claim 8, wherein releasing of the coating substance into the cavity in vapour form is achieved by heating a source tablet containing the coating substance, thereby to cause evaporation of the coating substance.

11. A method as claimed in claim 8, wherein the pressure in the cavity is lowered to an absolute pressure of between 1×10′³ and 1×10′¹ mbar.

12. A method as claimed in claim 8, wherein the pressure within the cavity is raised to an absolute pressure of between 1×10′¹ and 1×10² mbar by the bursts of air.

13. A method as claimed in claim 8, wherein the or each burst of air enters the cavity via a diffuser which is configured to induce the turbulent movement of air within the cavity.

14. A method as claimed in claim 8, wherein the method includes heating the chamber before the objects are placed within the chamber so that the chamber is at a relatively higher temperature than the objects within the chamber when the coating substance is caused to evaporate to form a vapour.

15. A method as claimed in claim 8, wherein the method includes maintaining the raised pressure in the cavity for an extended period before the pressure in the chamber is returned to atmospheric pressure and the objects are removed.

16. A method of coating a surface as claimed in claim 8, wherein the method includes coating surfaces of objects in the form of optical lenses, which are supported within the cavity in a stacked arrangement.
